(19) United States
(12) Patent Application Publication
(10) Pub. No.: US 2011/0210237 A1
(43) Pub. Date: Sep. 1, 2011

(54) METHODS AND SYSTEMS FOR MEASURING THE FREQUENCY RESPONSE AND IMPULSE RESPONSE OF OBJECTS AND MEDIA

(76) Inventor: Shmuel Sternklar, Rehovot (IL)

(21) Appl. No.: 13/010,810

(22) Filed: Jan. 21, 2011

(30) Foreign Application Priority Data
Jan. 21, 2010 (IL) 203449

(51) Int. Cl. H01L 31/00

(52) U.S. Cl. 250/214.1

(57) ABSTRACT

A method of optically probing an object(s) and/or a medium and/or an optical path. In some embodiments, a signal describing noisy light returned from an object(s) and/or a medium is analyzed. In some embodiments, this analysis includes spectral and/or temporal analysis.

### FIELD OF THE INVENTION

The invention relates to the field of optical sensing, radar and imaging. Specifically the invention relates to methods and systems for measuring the optical power frequency response and impulse response of objects and media.

### BACKGROUND OF THE INVENTION

Publications and other reference materials referred to herein, including reference cited therein, are incorporated herein by reference in their entirety and are numerically referenced in the following text and respectively grouped in the appended Bibliography which immediately precedes the claims.

### SUMMARY OF THE INVENTION

In a first aspect the invention is a method for measuring the optical power frequency response of an object or medium. the method comprises the steps of:
a. illuminating the object or medium with at least one source of optical radiation whose amplitude varies in time in a random fashion or with optical radiation that is modulated with a modulator that is driven by a random or pseudo-random electronic signal such that the spectrum of optical frequencies of the illuminating radiation comprises a bandwidth of frequencies around a center carrier frequency;
b. acquiring the power signal of the at least one illuminating optical radiation source as the output of a detector whose response time is slow compared with the center carrier frequency of the illuminating optical radiation;
c. acquiring the power signal of the radiation from the at least one radiation source that returns from the object or medium with a similar or the same detector;
d. determining from the power signals at least one of:
   i. the optical power frequency response of the object or medium;
   ii. the distance from the measurement system to one or more locations on the object or medium from which the radiation returning from the object or medium originates;
   iii. the relative distances between the locations on the object or medium from which the returning radiation originates
   iv. an impulse response of the object or medium.

One method of determining the characteristics of the optical power frequency response of the object or medium is:
a. using electronic means to determine the power spectral density (PSD) spectrum of the illuminating optical radiation from the measured power signal of the illuminating radiation;
b. using electronic means to determine the PSD spectrum of the returning optical radiation from the measured power signal of the returning radiation;
c. dividing the PSD spectrum of the returning radiation by the PSD spectrum of the illuminating radiation to determine the amplitude squared of the power transfer function spectrum.

When the characteristics of the optical power frequency response of the object or medium are determined in this manner, the inverse Fourier transform of the amplitude squared of the power transfer function is calculated. From the inverse Fourier transform a temporal correlation between the power signals of the illuminating radiation and the returning radiation is determined and from this correlation one or both of the following are determined: the distance from the measurement system to the locations on the object or medium from which the radiation returning from the object or medium originates and the relative distance between locations on the object or medium from which the returning radiation originates.

The electronic means used to determine the PSD spectrum can comprise at least one of the following: an electronic spectrum analyzer (ESA), an electronic correlator circuit, a memory device, a computer, electronic circuitry to carry out any of the required algebraic functions and other signal processing tasks.

Another useful power signal having a useful PSD spectrum can be determined by performing a summation of the power signal of the illuminating radiation and of the power signal of the returning radiation. The summation can be performed by directing at least a portion of the illuminating radiation and at least a portion of the returning radiation onto the same detector, or by summing the power signal of the illuminating radiation and of the returning radiation with an electronic summing circuit or computer.

Another useful power signal having a useful PSD spectrum can be determined by performing a subtraction of the power signal of the illuminating radiation and of the power signal of the returning radiation; alternately performing any algebraic calculation that is dependent upon the power signal of the illuminating radiation and the power signal of the returning radiation can be carried out to determine the resulting power signal having a PSD spectrum.

The method of the invention can be carried out by applying an optical delay on the optical path between the illuminating radiation and the detector of the illuminating radiation; by applying an optical delay on the optical path between the illuminating radiation and the detector of the radiation returning from the object or medium; or by applying an optical delay on the optical path between the illuminating radiation and the detector. Any of these methods can be carried out by splitting the illuminating beam into at least two paths whereby the at least two paths are of equal optical delay or of unequal optical delay.

The method of the invention can be carried out by applying a further optical modulation means on at least one of the following: 1) the radiation source; or 2) the radiation in at least one of the optical paths between the illuminating radiation and at least one of the detectors, where the modulation means can be one or more of the following: 1) amplitude modulation, 2) phase modulation, 3) frequency modulation, 4) polarization modulation. In particular, examples of possible amplitude modulation are 1) pulsed, 2)

sinusoidal, 3) amplitude modulation such that the autocorrelation of the power signal has a Gaussian dependence on time, 4) amplitude modulation such that the autocorrelation of the power signal has a super-Gaussian dependence on time.

Embodiments of the invention comprise applying a phase retrieval algorithm on the amplitude of the PSD spectrum to determine the phase spectrum associated with the PSD spectrum embodiment associated with the object or medium. These embodiments can further comprise determining the full complex optical power frequency response of the object or medium from the amplitude spectrum and the phase spectrum of the power transfer function spectrum in which case the method can further comprise performing an inverse Fourier transform of the full complex optical power frequency response to determine the optical power impulse response of the object or medium.

In a second aspect the invention is a system for determining the optical power frequency response and optical power impulse response of an object or medium. The system comprises:
a. at least one source that emits optical radiation whose amplitude varies in time in a random fashion or optical radiation that is modulated with a modulator that is driven by a random or pseudo-random electronic signal such that the spectrum of optical frequencies of the at least one source of illuminating radiation comprises a bandwidth of optical frequencies around a center carrier frequency;
b. one or more detectors adapted to detect the emitted optical radiation and whose response time is slow compared with the center carrier frequency of the electromagnetic radiation;
c. a detector whose response time is slow compared with the center carrier frequency of the electromagnetic radiation for detecting optical radiation returning from the object or medium;
d. electronic means for determining the power spectral density (PSD spectrum) from the output of the one or more detectors;
e. a computer or equivalent processing means comprising a memory and display means for analyzing the output of the electronic means and determining the optical power frequency response and the optical power impulse response of the object or medium; and
f. additional optical and electronic components needed to direct the emitted optical radiation from the source towards one of the detectors and towards the object or medium and to direct radiation returning from the object or medium onto one of the detectors.

The detector for detecting optical radiation returning from the object or medium can be the same detector used for detecting the illuminating radiation. The electronic means can comprise at least one of the following: an electronic spectrum analyzer (ESA), an electronic correlator circuit, a memory device, a computer, electronic circuitry to carry out any of the required algebraic functions and other signal processing tasks.

The source of the emitted optical radiation can be one of the following:
a. an amplified spontaneous emission (ASE) source;
b. spontaneous or stimulated scatter of optical radiation;
c. optical emission from atoms or molecules;
d. amplitude modulation of any light source with a modulator such that the signal is varying randomly, pseudo-randomly, or varying with some other type of modulation such that the spectrum of the source has relatively constant amplitude over the desired spectral width;
e. an optical frequency mixing technique based on a nonlinear mixing effect in a suitable nonlinear medium;
f. a light source displaying chaotic variations in light amplitude; and
g. Any light source with temporal modulation such that at least half of its power is situated in a spectral band Δf around f₀.

The components of the system of the invention can be arranged such that the radiation is returned from the object or medium by reflection, or transmission, or other type of deflection or scattering.

Embodiments of the system of the invention can be adapted such that the object or medium consists of one or more of the following:
a) An optical fiber;
b) The human body or any portion thereof;
c) Any type of biological medium; or
d) Any object or medium that is at least partially obstructed by another object or medium.

All the above and other characteristics and advantages of the invention will be further understood through the following illustrative and non-limitative description of embodiments thereof, with reference to the appended drawings. In the drawings the same numerals are sometimes used to indicate the same elements in different drawings.

### BRIEF DESCRIPTION OF THE DRAWINGS

FIG. 1 schematically shows a system that can be used for measuring the spectral response and impulse response of a target according to an embodiment of the invention that uses two separate detectors;

FIG. 2 schematically shows a system that can be used for measuring the distance to a target and locations of reflections from a target according to an embodiment of the invention that uses one detector;

FIG. 3 schematically shows an embodiment of the invention that is used to map the 3D topography of a target area;

FIG. 4 schematically shows another embodiment of the invention that is used to image objects that are behind a partially obscuring medium;

FIG. 5 schematically shows an embodiment of the invention that is used for locating points of power change (loss or gain) in an optical fiber;

FIG. 6 schematically shows an experimental setup;

FIG. 7 shows the reference spectrum of the source using the experimental setup of FIG. 6;

FIG. 8A and FIG. 8B respectively show the spectrum and impulse response of the returning light from two glass plates spaced 25 cm apart in the experimental setup of FIG. 6;

FIG. 9A and FIG. 9B respectively show the spectrum and impulse response of the returning light from two glass plates spaced 50 cm apart in the experimental setup of FIG. 6;

FIG. 10A and FIG. 10B respectively show the spectrum and impulse response of the returning light from three glass plates spaced 25 cm apart in the experimental setup of FIG. 6; and

FIG. 11A and FIG. 11B show the impulse response for fibers having a length of 2 meters and for a length of 18 meters respectively in an experiment in which the glass plates in the experimental setup of FIG. 6 were replaced with optical fiber of various lengths.

### DETAILED DESCRIPTION OF EMBODIMENTS OF THE INVENTION

In an embodiment of the invention, the optical EM radiation field has amplitude Eᵢₙ(t) that varies in time in a random or pseudorandom fashion and has a power sᵢₙ(t)=|Eᵢₙ(t)|² that is averaged over the averaging time of the measuring detector and associated electronics. This type of radiation naturally exists, for example, in sources of spontaneous emission as discussed in U.S. Pat. No. 5,034,678, which describes luminescent fiber amplifiers and semiconductor optical amplifiers. However, this type of radiation also includes other sources of optical “noise” radiation that have not been considered in the past, such as: spontaneous scattering and stimulated scattering e.g., Brillouin scattering and Raman scattering; parametric processes such as sum frequency generation, difference frequency generation, second harmonic generation, and all other types of parametric frequency mixing; and radiation from all types of optical media that are in an excited electronic state. This type of optical radiation can also be generated by modulating the light with a modulator that is driven by a random or pseudo-random electronic signal. The spectral characteristics of this signal are such that the average of the squared amplitude of the frequency spectrum PSDᵢₙ≡|Sᵢₙ(f)|² where PSD stands for power spectral density and Sᵢₙ(f) is the Fourier transform of sᵢₙ(t) is substantially constant over a frequency range from f=0 to f=Δf.

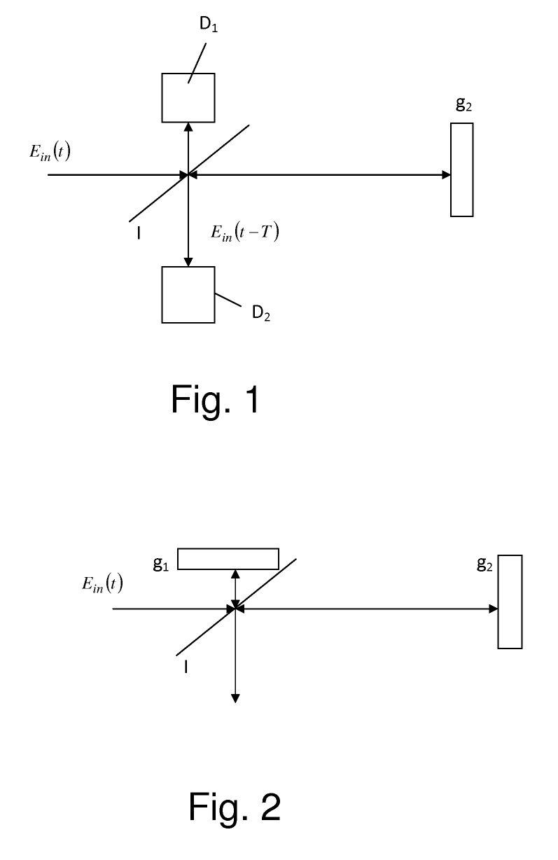

This spectrum is acquired, for example, as shown in FIG. 1 by acquiring sᵢₙ(t) as the output of detector D₁ on which the “noisy” optical field is directed and then analyzing its spectrum PSDᵢₙ with the aid of an ESA or other electronic means, where, the detector and associated electronics having a spectral response that covers the range of at least Δf. In this embodiment, a portion of the radiation illuminates the EM medium to be analyzed, and the radiation returning from the EM medium after reflection, transmission, or some other deflection angle is monitored with a similar detector D₂, where both detectors are characterized by a spectral range that is preferably at least Δf, so that the signal exiting the detector has a power sₒᵤₜ(t) and PSDₒᵤₜ which can be determined using an ESA or other suitable electronic means. A comparison of PSDₒᵤₜ to PSDᵢₙ, such as the transfer function PSDₒᵤₜ/PSDᵢₙ, will give a characteristic spectral transfer function PSD_{medium} of the EM medium, with extremely high resolution.

An application of this embodiment would be to determine the relative distances between the locations on the medium which are the sources of the radiation returning to the detector. This can be determined directly by the spectral transfer function, or, for example, by calculating the inverse Fourier transform of PSD_{medium} which gives a temporal correlation signal which peaks at temporal locations where the returning radiation originates, or by other means, such as that described as follows:

The correlation between the two power signals sᵢₙ(t) and sₒᵤₜ(t) is directly determined in a fashion known in the prior art by mixing the two signals in an appropriate mixing circuit while scanning the time delay τ of the reference signal sᵢₙ(t−τ) with respect to the optical signal from the target sᵢₙ(t−T). This gives a peak correlation at times τ=T from which the distance to the target can be determined.

A true power-impulse response and not a correlation-type of response would be beneficial. Means for determining the true power-impulse response are described herein below.

In the embodiment just described as well as in the other embodiments described herein it is possible to increase the optical frequency range in the following fashion: The medium is first irradiated with “noisy” EM radiation having a center frequency f₀ and bandwidth Δf. Then the signals are analyzed as described in the first embodiment. In the next step, the center frequency is changed to f₁=f₀+Δf while the noise characteristics are not changed so that the bandwidth Δf remains the same. Then the power signals are again analyzed as above. This process is repeated for N steps, where for each adjacent step fᵢ₊₁=fᵢ+Δf. In this fashion, the optical power response in a total optical bandwidth of N·Δf is measured with a spectral resolution determined by the electronic measuring means.

It will be obvious to those skilled in the art that there are numerous ways of carrying out the above embodiment. For example, the light source can be 1) a wavelength-tunable light source such as a laser that undergoes noise modulation through one of the various methods of producing noise that are known in the art or disclosed herein, or 2) an erbium doped fiber amplifier (EDFA) noise source that is split into N noise sources using, for example, a component known as a wavelength division demultiplexer, or 3) any light source characterized by a randomly varying amplitude and broad spectral bandwidth, and for which the center carrier frequency can be changed. In addition, it will be obvious that the N sequential measurement steps described in this embodiment can instead be carried out in parallel, through the use of a suitable optical means for separating the returning radiation from the target medium into N spectral windows, each of which are measured separately in an electronic measuring means that includes a detector and ESA or other electronic spectral measurement means. It will also be obvious that one or more of the spectral steps can be skipped, so that only a portion of the total optical spectrum width N·Δf will be measured.

Therefore, this invention has certain advantages over other spectral techniques that are applied to EM media. It allows for the acquisition of the spectral response of the medium to optical power signals with extremely high resolution, limited only by the electronic means, and can easily be on the order of 1 Hz or better. The spectral measurement is straightforward and relatively inexpensive. The types of spectral measurements include but are not limited to: spectral changes resulting from single or multiple specular reflections, single or multiple diffuse reflections, absorption, gain, and dispersion, where any of the above take place within or on the surface of the EM medium.

Before continuing with further embodiments, it is instructive to present the theory of scattering of “noisy” EM radiation, its' detection by a “slow” detector, and the conclusions regarding analysis of this system using well-known linear system characterization methods.

### Theory:

Given two EM fields E_{in,1}(t) and E_{in,2}(t) having power signals s_{in,1}(t)=|E_{in,1}(t)|² and s_{in,2}(t)=|E_{in,2}(t)|² respectively.

Suppose the medium consists of multiple scatterers and is illuminated with E_{in,1}(t). In this case, the output EM field is composed of the sum of the scattered fields from each scatterer:

$${E}_{out , 1} ( t ) = {\sum }_{n} {a}_{n} {E}_{in , 1} ( t - {T}_{n} ) ,$$

where Tₙ are time delays caused by the scatterers and aₙ are the corresponding coefficients.

The corresponding output power is then

$${s}_{out , 1} ( t ) = {\vert {E}_{out , 1} ( t ) \vert}^{2} = {\vert {\sum }_{n} {a}_{n} {E}_{in , 1} ( t - {T}_{n} ) \vert}^{2} = {\sum }_{n} {\vert {a}_{n} \vert}^{2} {s}_{in , 1} ( t - {T}_{n} ) + {\sum }_{n , m} {a}_{n} {a}_{m}^{*} {E}_{in , 1} ( t - {T}_{n} ) {E}_{in , 1}^{*} ( t - {T}_{m} )$$

However, if the medium varies in time, and/or if the EM field varies randomly in time, so that the interference term (the right-hand term) is zero after averaging, then

$$〈 {s}_{out , 1} ( t ) 〉 = {\sum }_{n} {\vert {a}_{n} \vert}^{2} 〈 {s}_{in , 1} ( t - {T}_{n} ) 〉 .$$

As a consequence the medium acts as a linear system for the average power. This can be seen as follows by checking that superposition holds in this system:

If the medium is illuminated with two fields such that

[symbol]

sᵢₙ(t) [symbol] =A [symbol] s_{in,1}(t) [symbol] +B [symbol] s_{in,2}(t)

[symbol]

Then

$$〈 {s}_{out} ( t ) 〉 = A {\sum }_{n} {\vert {a}_{n} \vert}^{2} {s}_{in , 1} ( t - {T}_{n} ) + B {\sum }_{n} {\vert {a}_{n} \vert}^{2} {s}_{in , 2} ( t - {T}_{n} ) = A 〈 {s}_{out , 1} ( t ) 〉 + B 〈 {s}_{out , 2} ( t ) 〉$$

which agrees with the superposition criterion. In addition, if the medium is time-invariant, then it can be characterized by the well-known principle of linear time-invariant (LTI) systems:

[symbol]

sₒᵤₜ(t) [symbol] =hₚ(t)* [symbol] sᵢₙ(t)

[symbol]

Sₒᵤₜ(f)=Hₚ(f)·Sᵢₙ(f)

where hₚ(t) is the power impulse response for the medium, Hₚ(f) is its' Fourier transform, Sₒᵤₜ(f) is the spectrum of sₒᵤₜ(t), and all the conclusions related to LTI systems can be applied here including the use of Fourier transforms and inverse-Fourier transforms which connects between the temporal power response and the spectrum of the power signal, as well as the use of the Kramers Kronig or other phase-retrieval analyses to determine the phase spectrum associated with Hₚ(f).

The spectral response of the specific embodiment that is shown in FIG. 2 is now analyzed. The system shown schematically in FIG. 2 is an embodiment that can be used, for example, for measuring the distance to a target as well as the relative distances between the locations on the target from which returning radiation originates, if more than one location exists. It utilizes only one detector, which is advantageous as compared to the use of two detectors, in terms of complexity, cost, and the complications that arise from the varying characteristics of the two detectors

The “noisy” radiation Eᵢₙ(t) is split by a beam splitter 1 into two beams. One beam is directed towards a “reference” reflector g₁ and the other to a target g₂, both of which reflect a portion of the radiation back towards beam splitter 1 where the reflected beams are combined to form the output beam Eₒᵤₜ(t). Therefore,

Eₒᵤₜ(t)=p₁Eᵢₙ(t)+p₂Eᵢₙ(t−T),

where T=2δL/c is the relative time-lag for the arrival at beam splitter 1 of the beam reflected from g₂ with respect to that arriving from g₁ due to a difference in propagation distance δL to the two elements, and p₁ and p₂ are the effective transmission coefficients of the beams through the system.

For the reasons discussed above, if the radiation is varying randomly in time, then the output power will be the sum

sₒᵤₜ(t)=|ρ|²(sᵢₙ(t)+sᵢₙ(t−T)),

where for simplicity it is assumed that |p₁|²=|p₂|²=|ρ|². This is the power that is measured with a detector having a suitable electronic bandwidth, where due to the time-response of the detector, it performs an averaging as well, so that the above represents the power after the averaging.

The Fourier transform of this signal is:

Sₒᵤₜ(f)=|ρ|²Sᵢₙ(f)(1+e^{-2πfT}).

Therefore in this case PSDₒᵤₜ for the sum of the two signals is:

PSD_{out,sum}≡|Sₒᵤₜ(f)|²=2|ρ|⁴|Sᵢₙ(f)|²[1+cos(2πfT], equation [1]

such as is measured with an electronic spectrum analyzer.

Note that the spectrum is sinusoidal, with a period that is dependent upon the distance between the two reflectors due to the time delay T. In order to acquire at least one cycle of this spectrum, it is necessary to measure the signal with an electronic bandwidth of approximately Δf=1/T=c/2δL. For example, for δL=10 cm, a bandwidth of 1.5 GHz is needed to acquire one full cycle of the spectrum. This information can then be used to determine the distance to the target, since the distance to the reference reflector g₁ is known. This model only treats the case of one reflection location on the target; however it can be extended to the case of more than one location, so that these locations can be determined as well.

In many situations it is sufficient to acquire the spectrum over a portion of the bandwidth Δf. This will reduce the electronic and detector bandwidth requirements accordingly, and will allow for increasing the detectors' active area, so that it will be more sensitive. For example, if the number of reflections from the target is known a priori, then it is possible through appropriate signal analysis, estimation and extrapolation techniques to measure the PSD_{out,sum} over a bandwidth that is smaller than Δf and still acquire knowledge of distance with a depth resolution δL that approx. corresponds to Δf

Therefore, in a variation of the embodiments described herein above, only a portion of the spectrum is measured by utilizing a bandwidth less than Δf. For example, in the case of one reflection from the target, only a portion of the sinusoidal cycle is measured, and the cycle period is determined through known signal estimation techniques and other signal analysis techniques. The ability to utilize a bandwidth less than Δf is advantageous since it relaxes the speed requirements on the detectors and other electronic components of the system.

It is pointed out that the power signal PSD_{out,sum} can also be obtained using the basic embodiment described earlier and shown schematically in FIG. 1. In this embodiment sᵢₙ(t) is measured with detector D₁, and sₒᵤₜ(t) with detector D₂. The power signal PSD_{out,sum} is then acquired by summing the detector outputs with a suitable electronic means, such as an electronic summing circuit.

In another variation of embodiment using only one detector, a further inverse-Fourier transform is performed on PSD_{out,sum} described in equation 1 to determine the correlation between the power signals returning from the target and that of the irradiation, which shows a characteristic peak at the time delay T, from which the distance to the target can be determined. As explained above, if more than one source of returning radiation exists on the target, their locations can be identified as well with this technique.

In a further embodiment, the outputs of one or both of the said detectors of FIG. 1 or FIG. 2 are stored in a suitable electronic memory device for processing.

It will be obvious to those skilled in the art that it is also possible to acquire the difference signal:

sₒᵤₜ(t)=|ρ|²(sᵢₙ(t)−sᵢₙ(t−T))

or any other algebraic function of the two signals through electronic means. This may serve to enhance the characterization of the target by improving the depth resolution, signal-to-noise ratio, depth range or other aspects of the measurement technique.

It will be obvious to those skilled in the art that further variations on the above embodiments are possible which will aid in reducing the required electronic bandwidth to values below Δf. In addition, if the target consists of more than one reflection, especially if the number of reflections is known a priori, then suitable signal processing techniques can be utilized for reducing the required bandwidth and determining the delay times to the reflecting surfaces with high accuracy.

Therefore, it is shown in these embodiments described above and further described below. that despite the fact that the signal is optical and the detector is ‘slow” relative to the EM field fluctuations, it is possible to measure important spectral and temporal characteristics of the medium's response to optical power signals, as well as its' distance to the measurement system and the locations of multiple reflections in the target medium, by analyzing the power signals associated with the noisy EM field, and not the EM fields themselves as is known in the prior art.

In addition to the above embodiments and applications, there will now be described embodiments for acquiring the optical impulse response of EM media. For example, a well-known technique known as pulsed laser radar for measuring the distance to the front of a remote object is to transmit a short pulse, on the order of nanoseconds, and measure the time it takes for the pulse to return to the detector. This technique is limited in depth resolution by the pulse length. This can be improved in principle by shortening the pulse width to have duration less than nanoseconds, but this comes at a significant cost in complexity and price. Moreover, this time-domain technique requires complex synchronization electronics. The invention disclosed herein overcomes these limitations by achieving high depth resolution without requiring short pulses.

In the embodiments described above, the true impulse response of the EM media (or “target”) to a pulse of EM power is not determined; rather, the temporal correlation function of the power signal returning from the media is determined. This is usually sufficient for media for which a small number of discrete scattering or reflection events take place.

If the target is more complex, e.g. consists of a large number of discrete scattering events, or continuously scatters the light in a diffuse fashion, then the PSD spectrum will accordingly be more complex as well. Examples of media of this type are: clouds, smoke, biological tissue, clothing, camouflage material, the atmosphere under certain conditions, optical fiber, bodies of water and other solids, liquids and gases under certain conditions. Under these conditions, a true impulse response is desired, since a correlation-type of response suffers from reduced temporal resolution and accuracy as opposed to the true impulse response, and so will not be able to temporally resolve the scattering behavior sufficiently. Even if the medium is not complex in terms of the number and type of scattering points, it would still be beneficial to know the true power impulse response, as opposed to the correlation-type of response.

An embodiment of the invention for determining the true power-impulse response of the EM medium is to carry out the following steps:
1. Determine PSD_{medium} as described in the first embodiment.
2. Calculate \sqrt{PSD_{medium}} which is the amplitude spectrum associated with the power transfer function spectrum for the medium.
3. Calculate the phase spectrum θ(f) associated with the said transfer function spectrum of the medium, through a phase-retrieval algorithm such the Kramers-Kronig technique, MEM technique or other techniques as described in, for example, co-pending International Patent Application WO 2009/098694 and U.S. Pat. No. 7,505,135 by the same applicant, the description of which, including publications referenced therein, is incorporated herein by reference; and
4. Calculate the true power impulse response of the medium by calculating the inverse Fourier transform of \sqrt{PSD_{medium}(f)}exp(iθ(f)).

This impulse response will reveal the relative distance to the various reflection or scattering points in the medium, as well as the overall scattering characteristics of the medium, such as the scattering coefficients, with a temporal resolution and accuracy significantly better than that of the power correlation signal technique.

In a similar fashion, the technique described in the steps above can be used for determining the distance to the target as well as the relative distances between scattering points in the target, by carrying out these 4 steps for the PSD_{out,sum} function as defined in eq. 1.

As stated above, a preferred source of EM radiation is one in which the radiation is varying randomly, either due to a natural process or due to an applied modulation. Several types of sources capable of performing this function are known in the art, and others are disclosed herein. For example a suitable source of EM radiation could be one of the following:
1. Amplified spontaneous emission (ASE) source, such as an erbium-doped fiber amplifier, semiconductor optical amplifier, or another type of medium which is in an excited state due to pumping and is emitting spontaneous or stimulated emission;
2. Spontaneous or stimulated scatter of optical radiation, such as caused by Brillouin scattering or Raman scattering;
3. Luminescence or Fluorescence or other type of EM emission from atoms or molecules;
4. Parametric frequency mixing such as sum-frequency generation, difference frequency generation, second harmonic generation or any other type of EM frequency mixing technique due to a nonlinear mixing effect in a suitable nonlinear medium.
5. Amplitude modulation of any light source with a suitable modulator such that the signal is varying randomly, pseudo-randomly, or varying with some other type of modulation such that the spectrum of the source has relatively constant amplitude over the desired spectral width.
6. A light source displaying chaotic variations in light amplitude, such as laser diodes or other lasers having chaotic temporal statistics.
7. Any light source with temporal modulation such that at least half of its power is situated in a spectral band Δf around f₀.

In certain embodiments, the light source is external to the medium to be measured.

In other embodiments, the light source is an integral part of the medium to be studied. For example, an optical fiber will partially scatter injected light in the form of Brillouin scatter and/or Raman scatter, depending upon the optical characteristics of the light source, as is known in the art. These scattering effects cause the light to fluctuate randomly with a characteristic noise bandwidth of approx. 30 MHZ for Brillouin, and significantly broader bandwidth for Raman (typically at least 30 GHZ). In these embodiments, it is possible to utilize the noisy optical radiation to characterize the same optical fiber that is its' source. Applications include: measurement of the fibers' length, strain, stress, temperature, and points of power loss or gain. This description is given as an example only. Any of the previous listed optical noise sources and others known in the art can be utilized to measure certain features of the noise source itself.

In some of the above embodiments, acquisition of the power signal of the illuminating radiation can be carried out continuously throughout the process of measuring the returning radiation from the medium, or in certain situations it can be measured only once at the beginning of the measurement process, or in certain situations only at certain times during the measurement process. The latter options are possible if the average spectral characteristics and temporal characteristics of the illuminating radiation do not change significantly throughout the said measurement process, so that the signal waveform of the illuminating radiation can be stored electronically and then extracted from memory to be applied as explained in the various embodiments.

It is also to be understood that in some of the embodiments, instead of measuring the power signal of the actual source used as the irradiating radiation, it is possible to substitute in its place a different source having noise statistical characteristics and/or power spectrum that is substantially the same as of that of the actual source used for illuminating the object or medium. So, for example, the object or medium can be irradiated with an irradiation source from the same or different location as the measurement system, and another “local” source which is part of the measurement system is used as described in the various embodiments, to determine the optical power frequency response or impulse response of the object or medium.

It is also to be understood that in some of the embodiments, instead of measuring the power signal of the source used as the irradiating radiation, it is possible to substitute in its place a simulated power signal or spectrum that closely resembles or is identical to the actual irradiating source in terms of the noise statistics or spectrum.

It will also be understood that in all of the embodiments, the use of one radiation source is not to be taken as a limitation. All of the embodiments can involve one or more radiation sources, where the noise characteristics of the sources may be fully correlated, partially correlated or have no correlation between them, and where the electromagnetic bandwidth of each of the sources may overlap fully, partially or not at all with each of the other sources.

In certain applications it will be advantageous to vary the optical delay of sᵢₙ(t) and/or of sₒᵤₜ(t) before one or both of the optical signals enter the detectors of FIG. 1, or FIG. 2 or other embodiments. This can be done by adding optical delay lines, which can consist of optical fiber of known lengths, or other optical elements such as mirrors, lenses and other components known in the art for causing an optical delay. The delay can be tunable or fixed. In addition, instead of adding one delay line for either or both of the signals, it is possible to split either or both of the optical signals into two or more delay lines or optical paths. This splitting can be done simultaneously into two or more delay lines, or by switching in tandem between two or more delay lines. The splitting mechanism can be a fiber coupler, beamsplitter, wavelength division demultiplexer, or any other component known in the art for splitting a light beam into two or more beams. The addition of optical delay can useful, for example, for increasing the depth range of the object or medium, for allowing measurements to be made on objects or media that are close to the measuring system, for improving the depth resolution of the measurement, as well as for achieving other improvements in the capabilities of the measuring system. In particular, by way of example, we point out that improving the depth resolution with this technique is of particular significance, since it enhances the resolution capabilities of the measurement beyond those allowed by the operating parameters of the measurement system, such as the bandwidth of the measurement Δf.

In certain applications it will be advantageous to add a further optical modulation means to the embodiments described herein. The modulation means will be applied on at least one of the following: 1) the radiation source; or 2) the radiation in at least one of the optical paths between the illuminating radiation and at least one of the detectors. This will add an additional source of modulation for the radiation which is already modulated in a “noisy” fashion as described herein. This is done in order to enhance the capabilities of the measurement system. This modulation can be at least one of the following types: amplitude, phase, frequency and polarization. In particular, examples of possible amplitude modulation are 1) pulsed, 2)

sinusoidal, 3) amplitude modulation such that the autocorrelation of the power signal has a Gaussian dependence on time, 4) amplitude modulation such that the autocorrelation of the power signal has a super-Gaussian dependence on time.

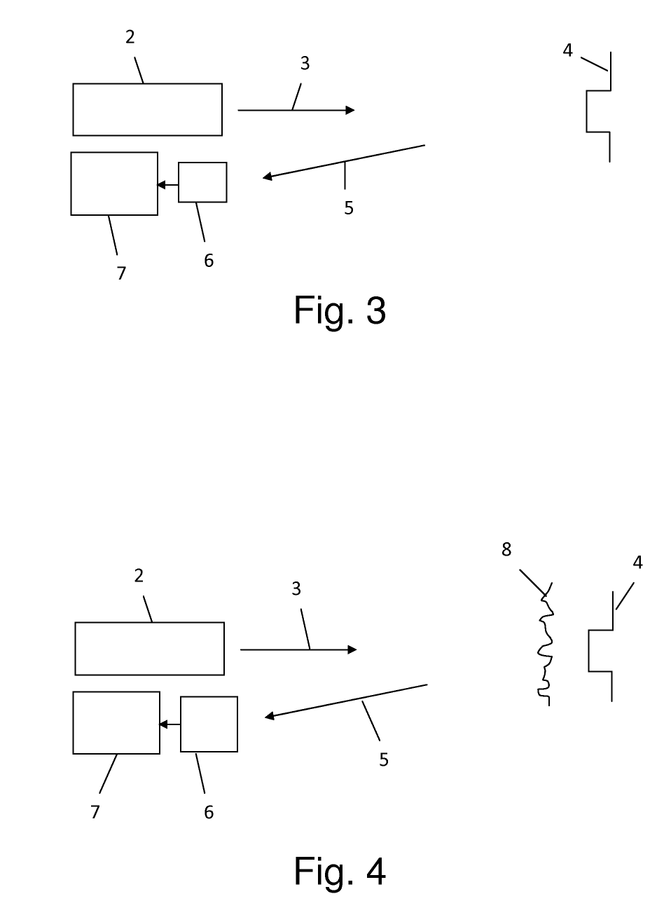

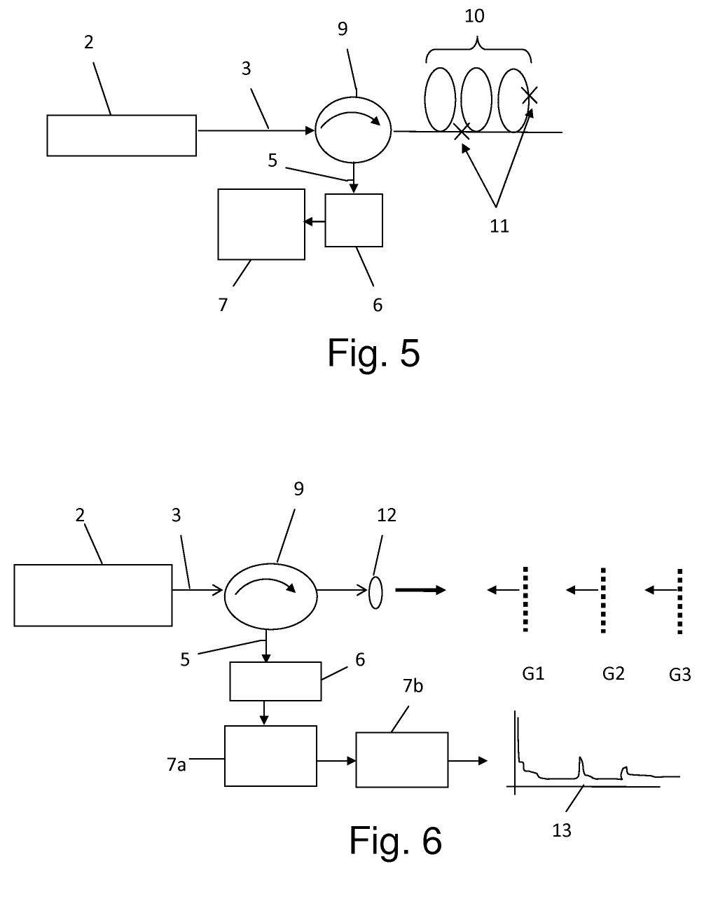

The present invention can be used in a wide range of applications. A non-limitative list of some of these applications includes:
1. FIG. 1 and FIG. 2 schematically show embodiments for measuring the distance to a target.
2. In another related embodiment, the invention is used to map the 3D topography of a target area, as schematically shown in FIG. 3, by scanning the beam transversally over the surface of the target and mapping the variations in the contour of the target. Instead of measuring one pixel of the target area at a given time, the whole or part of the transverse area of the target can be illuminated at once, and the returning radiation detected by one or more detectors, each of which monitors the radiation returning from one of the pixelated areas of the target surface. In a particular embodiment, these multiple detectors are situated in an array format. This description of the detection system is relevant for any of the embodiments described herein.
3. In another embodiment, the invention is used to image objects that are behind a medium, such as trees, other foliage, camouflage material or cloud cover, that partially obscures the object. FIG. 4 schematically shows the system. In this application, a preferred embodiment would be to determine the power impulse response of the target as described above, thereby revealing the distance to the sources of the multiple reflections.
   In FIG. 3 to FIG. 6: numeral 2 depicts the noisy source; numeral 3 the EM radiation with field Eᵢₙ(t); numeral 4 the object to be imaged; numeral 5 the EM radiation returning from the target with field Eₒᵤₜ(t) numeral 6 the detector which may be configured in any of the embodiments described herein; 7 the signal processing system consisting of an ESA, a computer, and/or other electronic means adapted to perform the spectral and/or temporal analysis as disclosed herein; and numeral 8 the medium that partially obscures the object.
   It is obvious that all of the figures herein are only schematic and are missing optical components for launching, collecting and detecting the EM radiation; specific means for measuring the source signal and spectrum, returning signal and spectrum and/or other components that are well-known to those skilled in the art that are necessary for carrying out the embodiments described herein as well as the directional EM beam control for scanning the target area. In addition, although the figures depict configurations whereby the exiting signal is reflected from the object, the invention is not limited to applications based on reflection configurations. It will be obvious to those skilled in the art that, in all embodiments of the invention, the illumination and detection geometry can involve reflection, transmission, or any other type of deflection of the radiation from the target
4. In another application, as shown in FIG. 5, the invention is used to measure characteristics of an optical fiber. In this figure numeral 9 represents an optical circulator, numeral 10 an optical fiber, and numeral 11 breaks, faults or other sources of power loss in the fiber. This embodiment of the invention can carry out all of the functions of a well-known device known as an optical time-domain reflectometer (OTDR), which measures points of optical loss along the fiber by sending pulsed light and measuring the pulse response reflected from the fiber.
   One of the main advantages of the present invention is that, as opposed to the OTDR device, it does not require pulsed light. This is advantageous, for example, if it is desired to shorten the “dead-zone”, i.e. the depth resolution, associated with the fiber measurement, which is proportional to the pulse length. In order to shorten the dead-zone in an OTDR device, the pulse length must be shortened. This adds complexity and cost to the system. In the technique of the present invention, which is not based upon pulsed radiation, it is significantly easier to shorten the dead-zone, by measuring the spectrum over a wider spectral range. The ability to shorten the “dead zone” without requiring a light source with shorter pulses is a basic advantage of the disclosed technique over all other types of pulsed radar systems.
   In a further embodiment of the invention, the ability to monitor the reflections from various points along an optical fiber is utilized to form the basis of a sensor of stress or strain on the fiber. For example, assume that the fiber has a series of N reflection points 1, 2, . . . , i, j, . . . N along its length that reflect a small portion of the radiation. These reflection points can be created, for example, with the use of connectors that physically bring the two fiber ends into a touching contact, and/or through the use of fiber Bragg gratings, which reflect a portion of the radiation whose spectral frequency and bandwidth match that of the grating's spectral response. If no pressure is on the fiber at any point, then the system of the invention will show pulsed reflections from each of the reflection points. However, if pressure is applied to a point along the fiber, e.g. between two adjacent reflectors i and j, then the system of the invention will detect this as a reduced reflection from the reflection points starting from point j. Those skilled in the art will understand that it is possible to design sensitive means for detecting pressure in this fashion, through various mechanical means of enhancing the optical loss from the fiber as a result of pressure. If fiber Bragg gratings are employed, then if pressure or strain is applied to one or more of the fiber gratings, then the spectral response of the grating changes, thereby changing the amount of reflection from that grating which can be monitored using a system of this invention.
5. It is to be understood that in all of the embodiments described herein, it is possible to irradiate the object under test, be it a fiber or any other medium, with two or more EM sources characterized by the random statistics described earlier, in order to enhance the measuring capabilities of the system, These sources can illuminate the medium from the same direction or from different directions. For example, in the optical fiber-based embodiments, it is possible to illuminate the fiber from both ends in order to measure the frequency and/or impulse response as seen from both ends of the fiber. It is also to be understood that if two or more light sources are used, they can be of the same center frequency so that their spectrums' overlap, or substantially of different center frequencies so that their spectrums' partially overlap or do not overlap at all.

### Experiments

An experimental setup is shown schematically in FIG. 6. An EDFA was used as the “noisy” light source 2. The output 2 from the EDFA passed through optical circulator 9 and was collimated and illuminated a target which consisted of one, two or three glass plates G1-G3, separated by approximately 25 cm. The returning light 5 was detected with a 1 GHz bandwidth detector and then sent to an ESA 7a for determining the PSD of the signal returning from the target. Finally, the data was processed in computer 7b and the impulse response displayed on a display device 13.

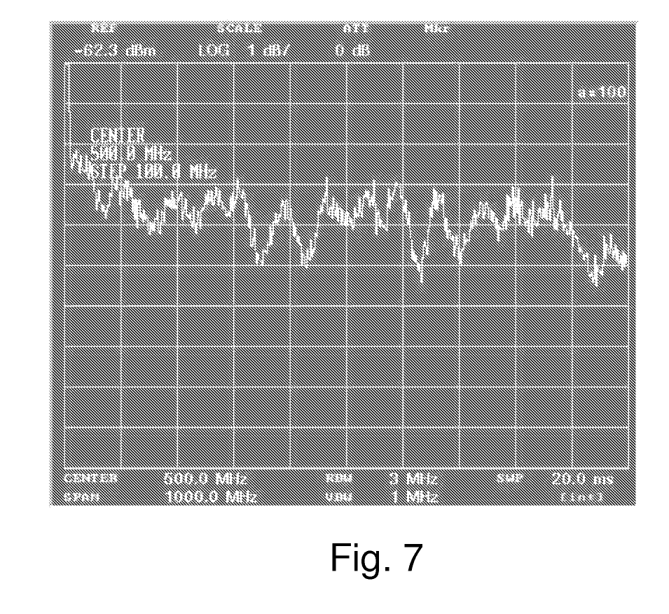

In the first experiment, the reference PSD spectrum of the source was established with the light returning only from plate G1. The spectrum after averaging is shown in FIG. 7.

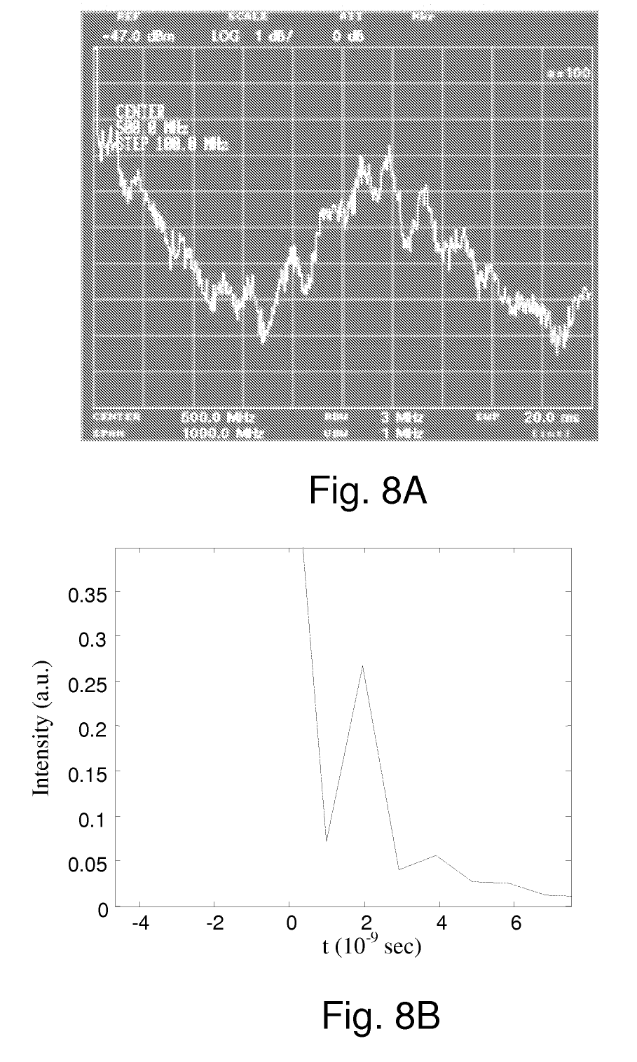

After measuring the reference, spectrum plate G2 was added at a distance of 25 cm. The resulting PSD spectrum and impulse response are shown in FIG. 8A and FIG. 8B respectively.

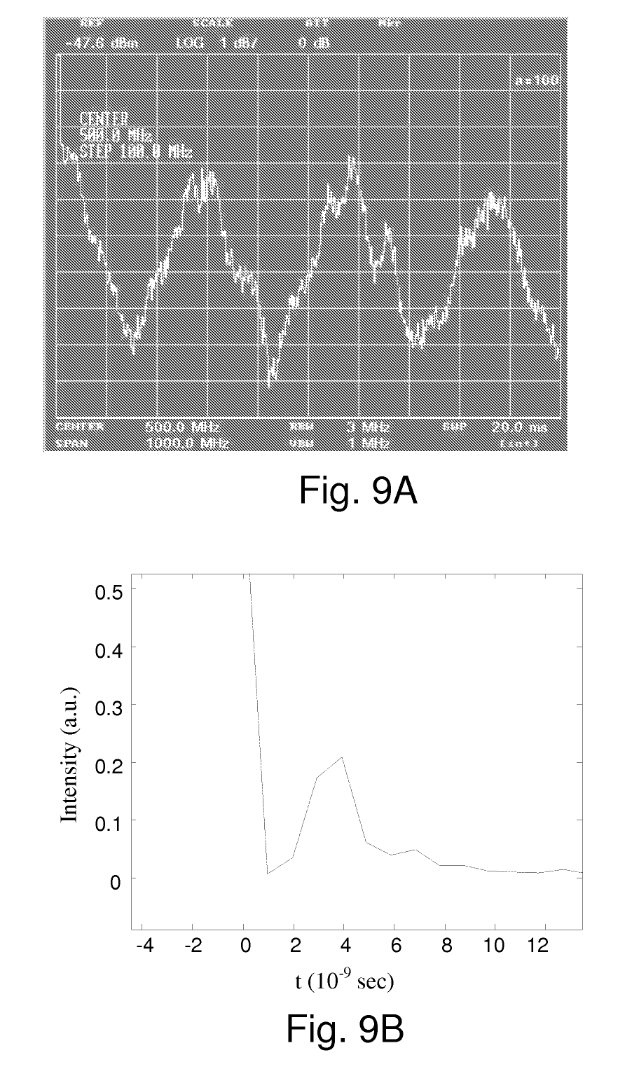

In the next experiment G2 was removed and G3 was inserted at a distance of 50 cm from G1. The resulting spectrum and impulse response are shown in FIG. 9A and FIG. 9B respectively.

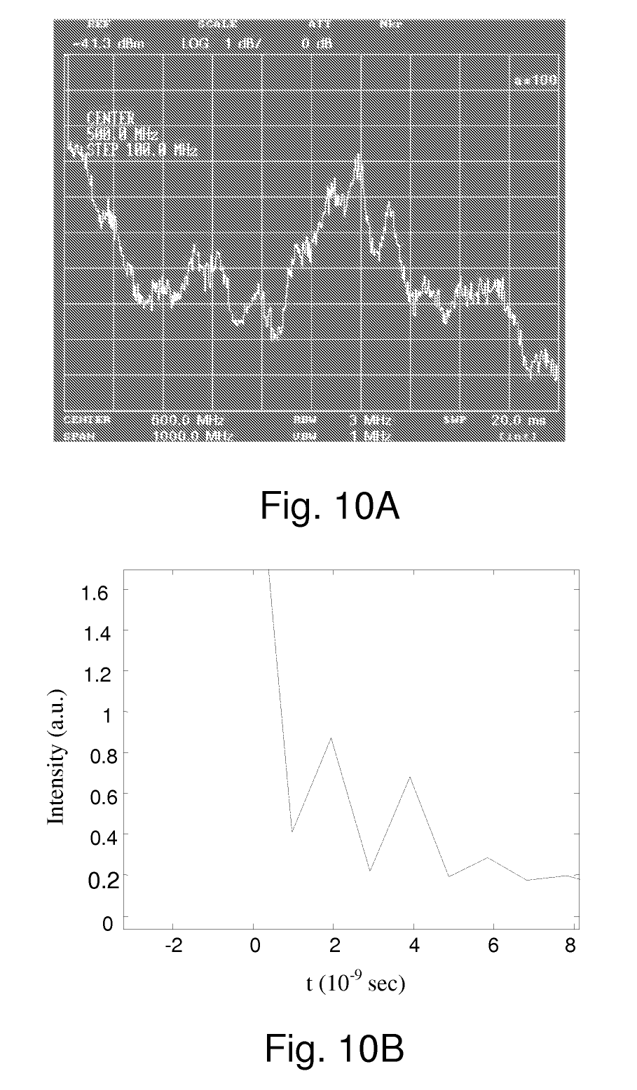

In the final experiment of this series G2 was reinserted so that all the plates were present. The resulting spectrum and impulse response are shown in FIG. 10A and FIG. 10B respectively.

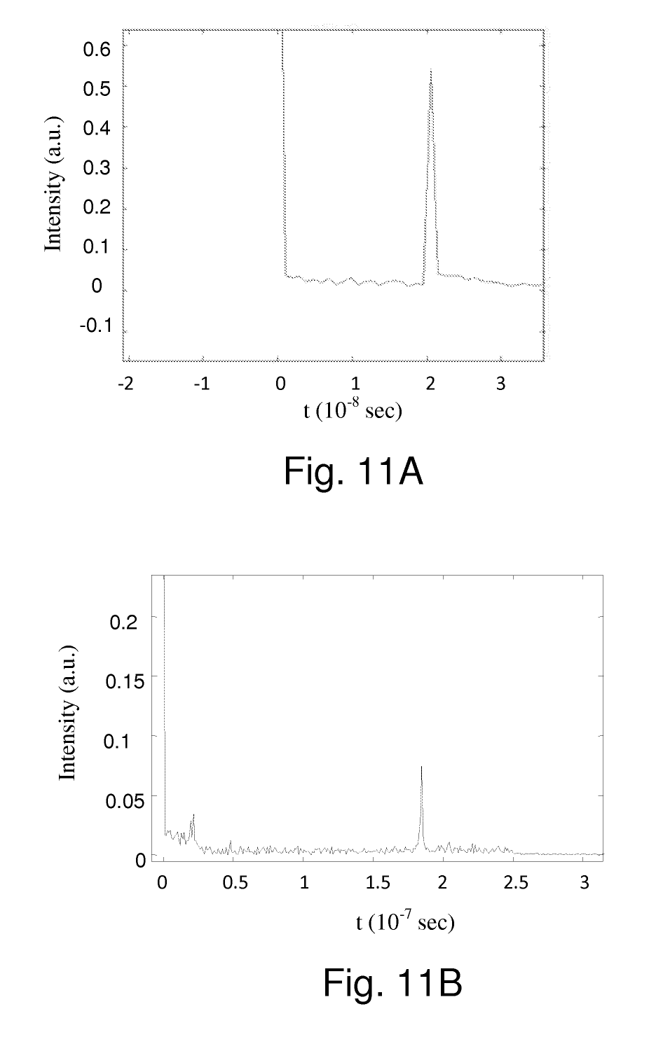

In another experiment the glass plates were replaced with optical fiber of various lengths. The FIG. 11A and FIG. 11B show the impulse response for a length of 2 meters and for a length of 18 meters respectively.

All of these figures show impulse responses that are in perfect agreement with the expected time-of-flight from the various reflection points along the target.

Although embodiments of the invention have been described by way of illustration, it will be understood that the invention may be carried out with many variations, modifications, and adaptations, without exceeding the scope of the claims.

### BIBLIOGRAPHY

[1] U.S. Pat. No. 6,392,585, Huff et al, “Random noise radar target detection device”, May 21, 2002.
[2] U.S. Pat. No. 6,864,834, Walton, “Radar system using random RF noise”, Mar. 8, 2005.
[3] T. Thayaparan and C. Wernik, “Noise radar technology basics”, Technical memorandum of Defense Research and Development, DRDC Ottawa TM 2006-266, December 2006
[4] Jiang et al, “Low coherence fiber optics for random noise radar”, in the MILCOM 2000-21st Century Military Communications Conference Proceedings, pp. 907-911 (2000)
5. U.S. Pat. No. 5,034,678, Eichen et al, “Method of and apparatus for measuring the frequency response of an electrooptic device using an optical white noise generator”, Jul. 23, 1991.
6. WO 2009/098694, Granot and Sternklar, “Methods and devices for analyzing material properties and detecting objects in scattering media”, Aug. 13, 2008.
7. U.S. Pat. No. 7,505,135, Granot and Sternklar, “Method and apparatus for imaging through scattering or obstructing media”, Mar. 17, 2009.

What is claimed is:

1) Apparatus for optically probing an object(s) and/or medium and/or optical path substantially according to any feature or combination of features described above and/or in the figures.

2) A method for optically probing an object(s) and/or medium and/or optical path substantially according to any feature or combination of features described above and/or in the figures.

3) A method of optically probing an object(s) and/or a medium and/or an optical path including the object(s) or medium, the method comprising:
a) illuminating the object(s) or the medium to induce, from the object(s) or medium, a plurality of noisy light response signals that are randomly or pseudo-randomly modulated, each induced noisy light response signal associated with a different respective target location of the object(s) or medium and with a different respective target-location-including optical path;
b) simultaneously receiving into an optical detector an optical superimposition of the plurality of noisy light response signals so as to generate a combination electrical signal describing the optically superimposed plurality of received noisy light response signals; and
c) determining or characterizing at least one of:
i) a relationship between power and frequency of the combination electrical signal or a derivative thereof over a discrete or continuous spectrum;
ii) a temporal autocorrelation function of the combination electrical signal.
